(19) United States
(12) Patent Application Publication
(10) Pub. No.: US 2008/0073763 A1
(43) Pub. Date: Mar. 27, 2008

(54) SEMICONDUCTOR DEVICE AND METHOD OF MANUFACTURING THE SAME

(75) Inventor: Wasarin Jungsuwadee, Gunma (JP)

Correspondence Address: FISH & RICHARDSON P.C., P.O. BOX 1022, MINNEAPOLIS, MN, 55440-1022, US

(73) Assignees: Sanyo Electric Co., Ltd., Osaka (JP); Sanyo Semiconductor Co., Ltd., Gunma (JP); Kanto SANYO Semiconductors Co., Ltd., Gunma (JP)

(21) Appl. No.: 11/860,751

(22) Filed: Sep. 25, 2007

(30) Foreign Application Priority Data
Sep. 27, 2006 (JP) 2006-261752

(51) Int. Cl. H01L 23/495; H01L 21/56

(52) U.S. Cl. 257/676; 438/127; 257/E23.031; 257/E21.502

(57) ABSTRACT

An object of the present invention is to improve heat dissipation of a semiconductor device, thereby preventing a semiconductor device from being destroyed by heat generation. To this end, provided is a semiconductor device including a lead frame, a semiconductor chip, and an island to which the semiconductor chip is fixed. In the semiconductor device, a recessed portion is formed in a center portion of the island, while the semiconductor chip is fixed to a peripheral portion of the island. According to this configuration, the recessed portion of the island is exposed to the outside of the package of the semiconductor device, or is located near the surface of the package. Accordingly, the recessed portion of the island absorbs heat generated from the semiconductor chip, and then dissipates the heat to the outside. As a result, the semiconductor device is prevented from being destroyed by the heat generation.

### BACKGROUND OF THE INVENTION

This invention claims priority from Japanese Patent Application Number JP 2006-261752 filed on Sep. 27, 2006, the content of which is incorporated herein by reference in its entirety.

1. Field of the Invention

The present invention relates to a semiconductor device and a method of manufacturing the same.

2. Description of the Related Art

In recent years, integration of semiconductor devices has been required for the purpose of meeting the demand for reducing the size of electronic devices. For this requirement, a semiconductor chip including electronic circuits integrated therein is fixed on a lead frame, and is then sealed with a resin.

FIGS. 14 and 15 show an example of such a semiconductor device. FIG. 14 is a cross-sectional view of a semiconductor device 51. FIG. 15 is a plan view for explaining a state where a semiconductor chip 53 is mounted on a lead frame 52 used for the manufacturing of the semiconductor device 51.

Hereinafter, the semiconductor device 51 will be briefly described. The semiconductor chip 53 is indicated by the thick rectangular line, and is mounted on an island 54. The island 54 has a rectangular shape. A plurality of leads 55, each having a first end arranged near a corresponding one of the four side edges of the island 54, are provided. In addition, conducting means 56 is provided on the first end of each of the leads 55 to electrically connect the lead 55 to the semiconductor chip 53, which is mounted on the island 54. Here, the conducting means 56 is a thin metallic wire made of Al, Au, or the like.

The lead frame 52 will be further described. Four hanging leads 57 extend respectively from the four corners of the island 54. The plurality of leads 55 provided on the four side edges of the island 54 are supported by tie bars 58.

This technology is described for instance in Japanese Patent Application Publication Nos. 2000-216324 and 2003-209216.

The aforementioned semiconductor device 51 includes any type of circuit, such as audio circuit, visual circuit, motor driver circuit, battery circuit and a power operational circuit, in each of which a power circuit is integrated as the number of semiconductor elements within the semiconductor chip 53 is increased. Such semiconductor devices may possibly be destroyed due to heat generated by the power circuit. Such destruction due to heat generation is not limited to the semiconductor devices each having the power circuit, but may also occur in a semiconductor device including a circuit, such as a CPU, that deals with a large number of signals at a high speed.

The above-described destruction due to heat generation is sometimes caused by a difference in thermal expansion coefficient among a semiconductor chip, a lead frame and a molding resin. The thermal expansion coefficient of silicon used for the semiconductor chip 53 is 3.2 ppm/° C. The thermal expansion coefficient of a copper material generally used for the lead frame 52 is 16.7 ppm/° C. In addition, the thermal expansion coefficient of an insulating resin used for molding is 8 to 10 ppm/° C., while the thermal expansion coefficient of Ag paste generally used for bonding the semiconductor chip 53 to the island 54 made of a copper material is 35 to 84 ppm/° C.

A material having a larger thermal expansion coefficient expands more greatly when heated. Suppose that a semiconductor device in which a semiconductor chip is bonded to a lead frame with Ag paste is heated. In this case, since the lead frame and the Ag paste expand more than the semiconductor chip does, deformation occurs in the bonding surfaces, which is likely to damage the semiconductor chip 53.

In the conventional semiconductor device 51, the semiconductor chip 53 is fixed on the island 54 having a flat surface, and then the semiconductor chip 53 and the island 54 are molded with an insulating resin 59. This structure allows heat to escape to the island 54 so that the above-described problem can be solved.

However, the resin has a poor thermal conductivity, thus producing a heat-insulating effect. Accordingly, heat generated from the semiconductor chip is likely to remain in the semiconductor chip and the island. As a result, there is still a problem that strain is likely to occur due to thermal expansion.

In addition, when the semiconductor chip 53 is fixed on the island 54 having the flat surface, it is necessary to apply a conductive paste 60 made of Ag or a solder to the entire back surface of the semiconductor chip 53. For this reason, there is a problem that the amount of the conductive paste is large.

Meanwhile, some semiconductor devices have a structure in which a heat sink portion is provided on the back surface of the island 54 separately from the island 54 so as to allow heat to escape. In this case, however, there is a problem of costs of manufacturing the heat sink portion in addition to the lead frame.

Some semiconductor devices have a structure in which: a pan-shaped island is formed by pressing the center portion of the island 54; a semiconductor chip is then fixed on the bottom of the pan-shaped island; and the back surface of the pan-shaped island is exposed from the resin mold. In this case, however, there is a problem that the semiconductor chip needs to be smaller than the area of the bottom portion of the pan-shaped island. Such semiconductor devices include, for example, LEDs, in which a pan-shaped island is used as a reflecting plate, electrodes and heat dissipating means. Since the LEDs have a small chip size, this problem is not so serious. However, this problem becomes serious in the case of an IC chip, such as a power MOS, having a larger chip size.

### SUMMARY OF THE INVENTION

The present invention has been made for solving the above-described problems.

A semiconductor device according to the present invention provides the following characteristics for the purpose of solving the above-described problems. Specifically, the semiconductor device includes a lead frame, a semiconductor chip, and an island on which the semiconductor chip is fixed. In addition, a recessed portion is provided in the center portion of the island, while the semiconductor chip is fixed on a peripheral portion of the island.

According to the above-described configuration, the recessed portion of the island is exposed to the outside of the package of the semiconductor device, or is located near the surface of the package. Accordingly, the recessed portion of the island absorbs heat generated from the semiconductor chip, and then dissipates the heat to the outside.

### BRIEF DESCRIPTION OF THE DRAWINGS

FIG. 1 is a cross-sectional view of a semiconductor device according to an embodiment of the present invention.

FIG. 2 is a plan view of the semiconductor device shown in FIG. 1.

FIG. 3 is a plan view of a lead frame that is used in the semiconductor device shown in FIG. 1.

FIG. 4 is a plan view of a lead frame that is used in another semiconductor device according to the present invention.

FIG. 5 is a plan view of a lead frame that is used in still another semiconductor device according to the present invention.

FIG. 6 is a plan view of a lead frame that is used in yet another semiconductor device according to the present invention.

FIG. 7 is a plan view of the lead frame that is used in the semiconductor device shown in FIG. 1.

FIG. 8 is a plan view showing a state where a semiconductor chip is mounted on the lead frame shown in FIG. 3.

FIG. 9 is a plan view showing a state where a semiconductor chip is mounted on the lead frame shown in FIG. 4.

FIG. 10 is a cross-sectional view of a semiconductor device according to another embodiment of the present invention.

FIG. 11 is a cross-sectional view of a semiconductor device according to still another embodiment of the present invention.

FIG. 12 is a cross-sectional view of a semiconductor device according to yet another embodiment of the present invention.

FIG. 13 is a cross-sectional view of a semiconductor device according to further another embodiment of the present invention.

FIG. 14 is a cross-sectional view showing a conventional semiconductor device.

FIG. 15 is a plan view showing the conventional semiconductor device.

FIG. 16 is another cross-sectional view showing the conventional semiconductor device.

### DETAILED DESCRIPTION OF THE PREFERRED EMBODIMENTS

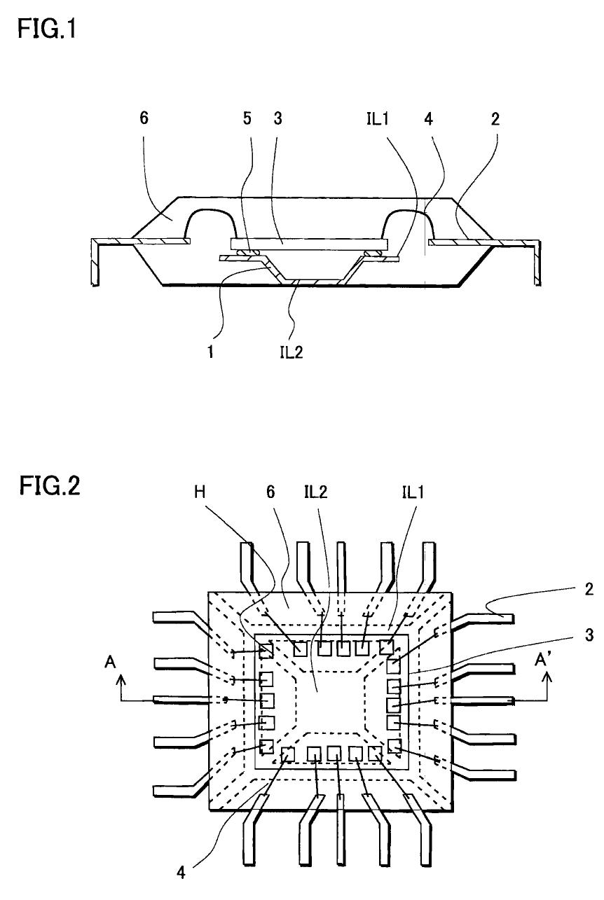

Descriptions will be given of embodiments of the present invention with reference to FIGS. 1 and 2.

FIG. 1 is a cross-sectional view of a semiconductor device according to the present invention, which is taken along the line A-A′ in FIG. 2. The semiconductor device includes an island 1, leads 2, a semiconductor chip 3, thin metallic wires 4, a conductive paste 5, and a resin mold portion 6. The thin metallic wire 4 is a type of conducting means. The conductive paste 5 is made of a conductive adhesive material, while the resin mold portion 6 is made of an insulating resin.

The island 1 is made of a conductive material. For example, the island 1 is made of a conductive material having copper (Cu) as a main component, or is made of Fe—Ni. In addition, the island 1 includes a first island IL1 and a second island IL2. The first island IL1 has a ring shape in the plan view, while the second island IL2, which is made of the same conductive material as that of the first island IL1, is provided at a position surrounded by the first island IL1. The second island IL2 is supported by the first island IL1 with hanging means H in between. The hanging means H are made of the same conductive material as that of the first and second islands IL1 and IL2, and are formed by, for example, pressing or etching a Cu foil or a Cu plate. Moreover, the semiconductor chip 3 is fixed on the first island IL1. In this embodiment, the semiconductor chip 3 is fixed thereon with a silver (Ag) paste, as an example. Here, the conductive fixing material is used for electrically connecting the back surface of the semiconductor chip 3 and the island IL to each other. However, when such electrical connection is unnecessary, an insulating adhesive agent having an excellent thermal conductivity may be used instead. As the conductive fixing material used here, a gold (Au) paste or a solder may alternatively be used.

One of the features of the present invention relates to the second island IL2. According to this embodiment, the second island IL2 has a rectangular shape, and the hanging means H extends to the first island IL1 from each of the four corners of the second island IL2. However, the shape of the second island IL2 is not limited to the rectangle, and also it is sufficient to provide at least one hanging means for securing the position of the second island IL2. However, for the purpose of stabilizing the position of the second island IL2, at least two hanging means, or more preferably, four hanging means may be provided. In addition, the four hanging means H may not necessarily extend respectively to the four corners of the first island IL1. In other words, each of the four hanging means H may be displaced from a corresponding one of the four corners of the first island IL1. The second island IL2 is formed by being pressed downward from above to be positioned lower than the first island IL1. The back surface of the second island IL2 is thus exposed from the back surface of the resin package. Although the second island IL2 is exposed from the resin mold portion 6 in this embodiment, the second island IL2 may not necessarily be exposed therefrom, and may be in a state of being covered with a thin resin layer.

Since the second island IL2 is exposed to the outside of the resin mold portion 6, or the second island IL2 is not exposed but covered with the very thin resin, the semiconductor device having an effective heat dissipation can be achieved.

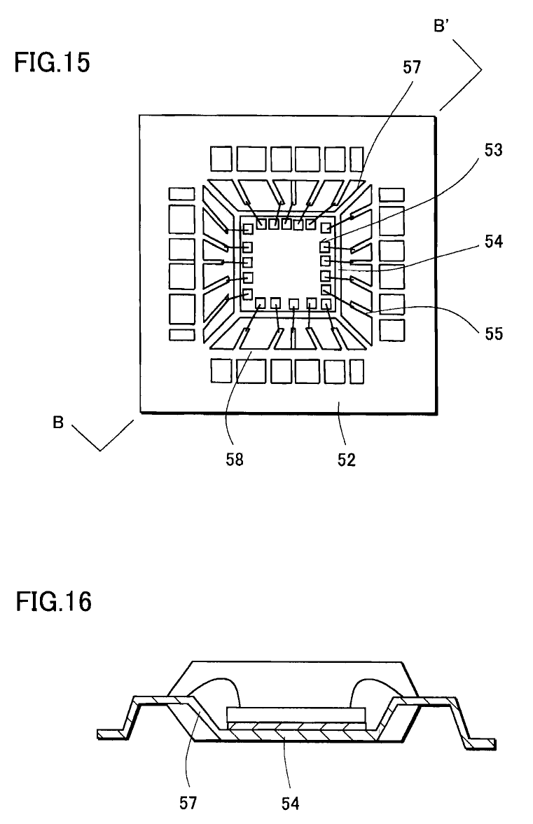

In addition to the improvement in heat dissipation, it is also possible to eliminate the limitation on chip size. In the conventional semiconductor device, the island 54 is pressed downward to be exposed from the insulating resin 59. FIG. 16 is a cross-sectional view, which is taken along the line B-B′ in FIG. 15, and which shows the structure of the conventional semiconductor device. In this structure, each of the hanging leads 57 is pressed obliquely downward from a vicinity of a portion to which a thin metallic wire is bonded, and the hanging leads 57 are then integrated with the island 54 at a lower position. Accordingly, a semiconductor chip having the same size as the island 54 can be mounted on the island 54, but a chip having a size larger than that of the island 54 is difficult to mount thereon because the hanging leads 57 extend obliquely.

By contrast, in the present invention, the second island IL2 is pressed downward, so that the back surface of the second island IL2 is exposed from the resin mold portion 6. This makes it possible to mount chips having various sizes on the first island IL1 while exposing the island from the back surface of the resin mold portion as in the same manner as that of the conventional case. In addition, by displacing the inner side edge L1 of the first island IL1 more inward, a chip having a smaller size can be mounted. A chip that is so large as to protrude from the outer side edge L2 of the first island IL1 can be mounted as well.

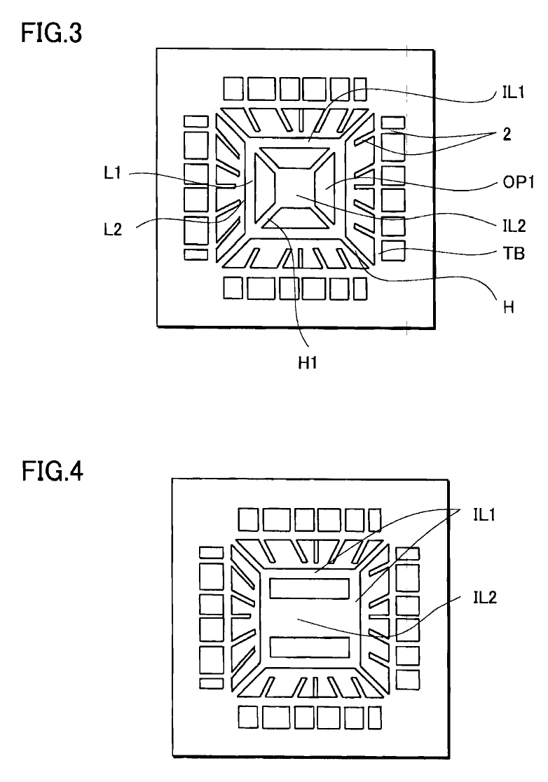

As described above, employing the lead frame of the present invention makes it possible to allow some flexibility in size of chips to be mounted, even if the semiconductor device has a structure in which the island 1 is exposed from the back surface of the resin mold portion 6. The lead frame having a thin plate shape is formed in the following manner. First of all, the rectangular island IL, the lead 2 around the island IL, the hanging leads H, and the tie bar TB are formed by a pressing or an etching technique At this time, the first and second islands IL1 and IL2 have not been formed yet, and regions corresponding to these islands are positioned on the same plane. Thereafter, a region surrounding the portion corresponding to the second island IL2 is hollowed except portions corresponding to the hanging means H1. In other words, opening portions OP1 are formed between the first island IL1 and the second island IL2. FIG. 3 shows the shape of the opening portions OP1. Then, the region corresponding to the second island IL2 is pressed downward, so that a recess is formed.

Around the second island IL2, the hanging means HI and the opening portions OP1 exist. These opening portions OP1 facilitate the press by which the second island IL2 is pressed downward. In addition, these opening portions OP1 allow the insulating resin in a liquid state to be flown into the recessed portion, thus providing an effect of preventing air from remaining in the resin mold, particularly at the recessed portion.

A second feature of the present invention relates to a region where the island and the semiconductor chip are bonded to each other (here, referred to as a “bonded region”). In the conventional structure, for the purpose of closely bonding the island and the semiconductor chip to each other, a conductive paste is firstly applied to the entire bottom surface of the semiconductor chip, and then the semiconductor chip is bonded to the surface of the island. In the present invention, the periphery of the second island IL2 is surrounded by the ring-shaped first island IL1, while the second island IL2 is pressed downward. Accordingly, the conductive paste 5, which is made of the conductive adhesive material, is applied to only the surface of the ring-shaped first island IL1. For this reason, the area of the bonded region between the island and the semiconductor chip is reduced, that is the area in which a stress is generated is reduced. This makes it possible to reduce the stress among the back surface of the semiconductor chip, the island, and the conductive adhesive material. In addition, the need for applying the conductive paste 5 to the center portion surrounded by the ring-shaped first island IL1 is eliminated, the amount of the conductive paste 5 to be used can be reduced. Since the conductive paste 5 is normally made of a noble metal such as Ag, the reduction in the amount of the conductive paste 5 leads to a reduction in manufacturing cost of the semiconductor device. The same holds true as well for a case where another conductive adhesive material or an insulating adhesive material is used instead.

A third feature of the present invention relates to a difference in size of the semiconductor chip in comparison to a semiconductor device having the conventional heat sink structure. In the conventional heat sink structure, as shown in FIGS. 14 and 16, an island is pressed downward, and a semiconductor chip is then fixed to the center portion. In this case, since the size of the semiconductor chip is limited within the size of the island 54, a semiconductor chip having a larger size cannot be fixed. In the present invention, a semiconductor chip is fixed not to the second island IL2, which is the recessed portion of the island, but to the first island IL1, which surrounds the recessed portion, so as to solve this problem. The fixation of the semiconductor chip to the first island IL1 makes it possible to fix a semiconductor chip having a size larger than that of the island.

Moreover, it is also possible to fix a semiconductor chip smaller than the area of the island.

As described above, in FIG. 3, the hanging means H1 are formed between the first island IL1 and the second island IL2. These hanging means H1 facilitates the bending process for pressing the second island IL2, while allowing the resin to be flown into the recessed portion. However, a structure as shown in FIG. 4 may also be employed. What is essential is that the portion of the second island IL2 can be pressed down, and accordingly the hanging means H1 may be provided at two sides facing each other among the four sides of a portion corresponding to the second island L2.

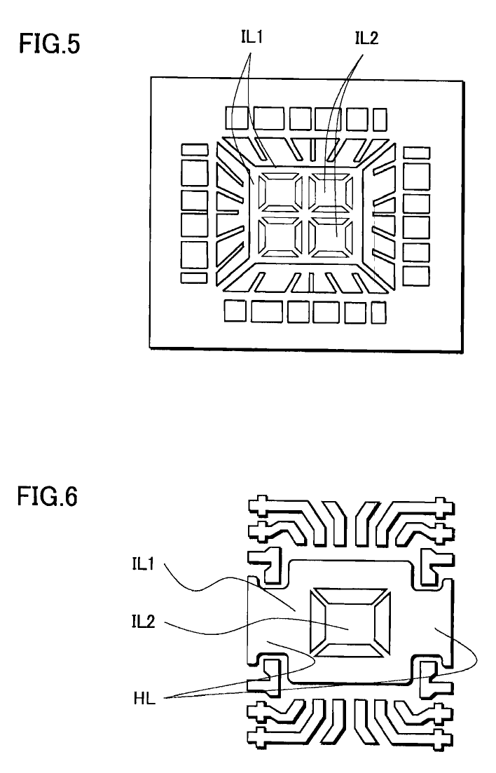

FIG. 5 also shows another structure for carrying out the present invention. In this structure, an island 1 includes a first island IL1 and plural second islands IL2. The first island IL1 has a ring shape in the plan view, while the plural second islands IL2 are provided at positions surrounded by the first island IL1. The second islands IL2 may be formed, as shown in FIG. 5, in a manner that two of the second islands IL2, each having a rectangular shape, are aligned in each vertical line. Alternatively, each of the second islands IL2 may have a shape other than the rectangular shape, and the number of the second islands IL2 is not limited to four.

FIG. 6 also shows still another structure for carrying out the present invention. In this structure, an island 1 includes a first island IL1 and a second island IL2. The first island IL1 has a ring shape in the plan view, while the second island IL2 is provided at a position surrounded by the first island IL1. In addition, two sides, facing each other, of the island 1 having a rectangular shape are integrated with a heat-dissipating lead HL, which is exposed from the resin mold 6. With this structure, heat can be dissipated, not only from the second island IL2, but also from the heat-dissipating lead HL. As a result, heat can be dissipated more efficiently.

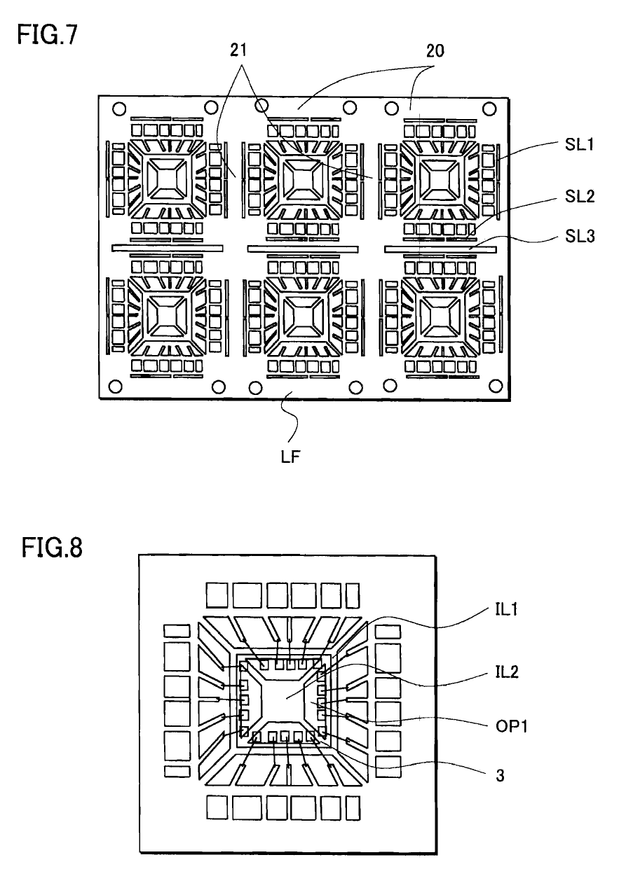

Subsequently, the lead frame LF will be briefly described with reference to FIG. 7. In the lead frame LF, units each shown in FIG. 3 are arranged in a matrix. Each unit including the island 1, the plurality of leads 2 and the tie bars TB is formed in a portion surrounded by a pair of connecting strips 20 and a pair of connecting strips 21. The connecting strips 20 extend in the lateral direction, while the connecting strips 21 extend in the vertical direction. Each island 1 includes the first island IL1, the second island IL2, and the hanging means H1. Each lead 2 has a first end positioned in a vicinity of the first island 1, and extends radially outward. Each tie bar TB connects the leads 2 with one another. In addition, slits SL1 to SL3 are provided near second ends of the leads 2 so as to prevent the lead frame LF from buckling. All these components are formed of conductive materials, and copper is generally used as the main material of these components. When the pattern of the lead frame LF is formed, that is, when the pattern is formed by means of press cutting or etching, all the components are on the same plane. Thereafter, the second island IL2 is pressed downward to be formed in a shape forced out downward.

FIG. 8 is a plan view showing a state where the second island IL2 is pressed down, and concurrently where the semiconductor chip 3 is fixed on the first island IL1. The semiconductor chip 3 is indicated by a thick solid line, and is mounted on the first island IL1. As is clear from FIG. 8, the first island IL1, the second island IL2, and the back surface of the semiconductor correspond to the recessed portion. It will be understood that the resin cannot be filled in the recessed portion without the opening portion OP1. According to the structure of the present invention, since this opening portion OP1 is formed, the resin can be filled even after a semiconductor chip is mounted.

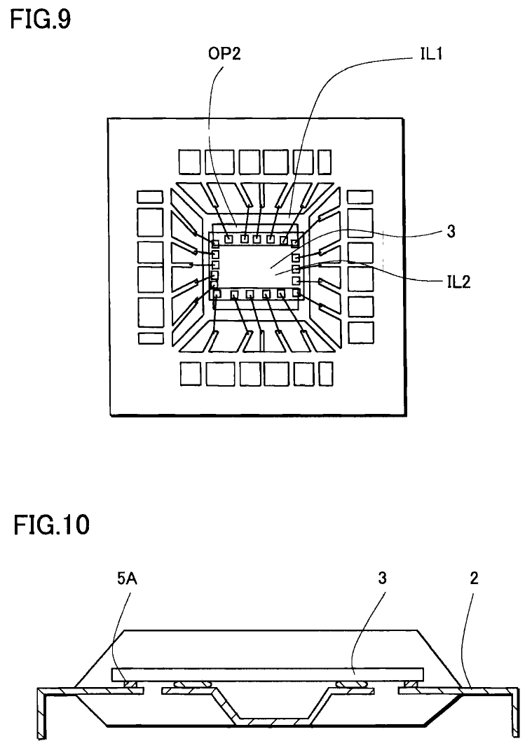

FIG. 9 is a plan view showing a state where the semiconductor chip 3 is mounted on the lead frame shown in FIG. 4. The semiconductor chip 3 is indicated by a thick solid line, and is mounted on the first island IL1. The semiconductor chip 3 is fixed to two sides, facing each other, of the first island IL1, while a gap OP2 exists between the first island IL1 and the semiconductor chip 3, on each of the other two sides of the first island IL1. Providing the gaps OP2 allows the resin to be flown through the gaps OP2 at the time of resin sealing. Accordingly, as shown in this example, the present invention can be achieved even without providing the hanging means, which connect the first island IL1 and the second island IL2 to each other.

FIG. 10 is a cross-sectional view for explaining a semiconductor device that is slightly different from the embodiment shown in FIG. 1. In this case, the semiconductor chip is mounted facedown, and a bonding pad positioned on the surface of the chip is directly connected with the lead 2. As conducting means 5A, which connects the semiconductor chip 3 and a lead 2 with each other, a conductive paste or a bump may be used. The material for the conducting means 5A includes solder, Ag and Au.

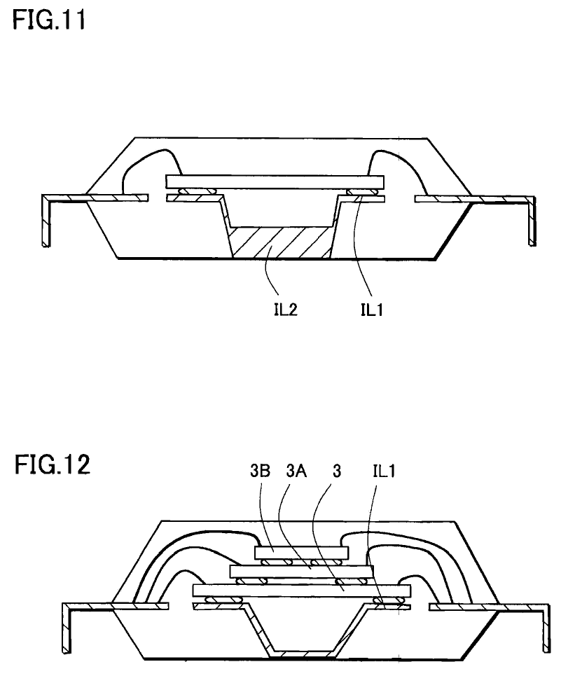

FIG. 11 is a cross-sectional view for explaining another semiconductor device that is slightly different from the embodiment shown in FIG. 1. In this case, a second island IL2 has a thick bottom. The second island IL2 having such thick bottom may be obtained by fixing a metallic member, which is to be used as a heat sink, to the bottom portion of the second island IL2. Alternatively, this second island IL2 may be obtained in the following manner. A thick metallic plate is prepared, and the second island IL2 having a thick portion is firstly formed of the thick metallic plate. Then, the lead frame is formed by press cutting as shown in FIG. 5. Thereafter, the second island IL2 is pressed downward, and subsequently a chip is mounted on the first island IL1 and then molded.

In FIG. 12, plural chips are stacked in the embodiment shown in FIG. 1. Here, semiconductor chips 3A, 3B, . . . are stacked on the upper portion of the semiconductor chip 3, which is fixed on the first island IL1. Each of the semiconductor chips 3A, 3B, . . . is connected to a lead with conducting means. Moreover, these semiconductor chips 3A, 3B, . . . may be stacked on the semiconductor chip 3 with a bump or a conductive paste when through electrodes each penetrating from the front surface to the back surface of the semiconductor chips are formed. Accordingly, this semiconductor device can be achieved without using thin metallic wires.

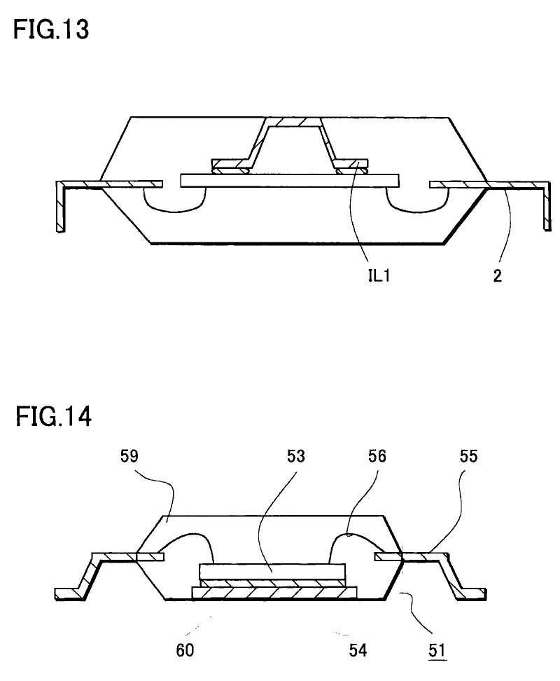

FIG. 13 is a cross-sectional view of another semiconductor device that is different from the embodiment shown in FIG. 1. This semiconductor device has a structure in which a recessed portion of an island is recessed upward of the semiconductor device. A semiconductor chip is fixed to the bottom portion of a first island IL1, while the semiconductor chip is connected to a lead with conducting means. This semiconductor device is obtained by changing the direction in which the lead 2 of the semiconductor device shown in FIG. 1 is bent, from the downward direction, to the upward direction.

Heat generated from the semiconductor chip is dissipated from the package to the outside through the recessed portion of the island. Accordingly, thermal expansion of the lead frame and the conductive paste is suppressed, so that deformation at the fixed portion of the lead frame and the conductive paste to the semiconductor chip is reduced. As a result, the semiconductor device is prevented from being destroyed. In addition, since the semiconductor chip is fixed to the peripheral portion of the island, deformation at the fixed portion in the bonded region is further suppressed. Moreover, since the area to which the conductive paste is applied is reduced, the amount of expensive noble metals to be used is reduced. As a result, the manufacturing costs can be reduced.

Moreover, it is possible to mount a semiconductor chip having a large area, in comparison to a type of semiconductor device in which a semiconductor chip is fixed to a bottom portion of a recessed portion of an island.

Furthermore, while a space is formed in the recessed portion by the recessed portion and the semiconductor chip, the opening portions are formed in the island positioned between the bottom surface and the peripheral portion. Accordingly, the insulating resin can be filled in the space at the recessed portion from the opening portions, so that unfilled portions are eliminated. As a result, burst and the like due to thermal expansion can be prevented.

What is claimed is:

1. A semiconductor device comprising:
an island on which a semiconductor chip is fixed;
a plurality of leads each having a first end extending to a vicinity of the island;
the semiconductor chip which is fixed on the island;
conducting means which electrically connects the semiconductor chip and the leads to each other; and
an insulating resin with which the semiconductor chip, the island, the conducting means and the leads are sealed, wherein
a center portion of the island is recessed relative to a peripheral portion thereof, and
the semiconductor chip is fixed to the peripheral portion of the island.

2. A semiconductor device comprising:
an island on which a semiconductor chip is fixed;
a plurality of leads each having a first end extending to a vicinity of the island;
the semiconductor chip which is fixed on the island;
conducting means which electrically connects the semiconductor chip and the leads to each other;
an insulating resin with which the semiconductor chip, the island, the conducting means and the leads are sealed; and
hanging means, wherein
the island includes a first island which has a ring shape, and a second island which is provided at a position surrounded by the first island,
the second island is supported by the first island using the hanging means, and is positioned lower than the first island, and
the semiconductor chip is fixed to the first island.

3. A semiconductor device comprising:
an island on which a semiconductor chip is fixed;
a plurality of leads each having a first end extending to a vicinity of the island;
the semiconductor chip which is fixed on the island;
conducting means which electrically connects the semiconductor chip and the leads to each other; and
sealing means with which the semiconductor chip, the island, the conducting means and part of the leads are sealed, wherein
the semiconductor chip is fixed to a peripheral portion of the island,
a center portion of the island is recessed relative to the peripheral portion, and
the back surface of the recessed portion is exposed from one surface of the sealing means.

4. The semiconductor device according to any one of claims 1 to 3 wherein the conducting means is any one of a thin metallic wire, a solder, a conductive paste, a bump and a conductive plate.

5. The semiconductor device according to claim 2 wherein the hanging means integrally extends, from each of the four corners of, or a vicinity of each of the four corners of, the second island, toward the first island.

6. The semiconductor device according to any one of claims 1 to 3 wherein a plurality of aforementioned second islands are provided in positions surrounded by the first island.

7. The semiconductor device according to any one of claims 1 to 3 wherein the recessed portion in the center of the island is recessed upward.

8. The semiconductor device according to any one of claims 1 to 3, wherein a plurality of the semiconductor chips are stacked on the island.

9. A method of manufacturing a semiconductor device that includes: an island having a peripheral portion, to which a semiconductor chip is fixed, and a recessed portion formed by recessing a center portion surrounded by the peripheral portion, and having a bottom surface; a plurality of leads each having a first end extending to a vicinity of the island; the semiconductor chip which is fixed to the island; conducting means which electrically connects the semiconductor chip and the leads to each other; and an insulating resin with which the semiconductor chip, the island, the conducting means and the plurality of leads are sealed, the method comprising the steps of:
forming an opening portion in the island at a position between the bottom surface and the peripheral portion; and
filling the insulating resin in the recessed portion through the opening portion.
